(19) United States
(12) Patent Application Publication
(10) Pub. No.: US 2025/0081769 A1
(43) Pub. Date: Mar. 6, 2025

(54) CONNECTING WIRE INSIDE SUPPORT MEMBER AND DISPLAY DEVICE HAVING THE SAME

(71) Applicant: Samsung Display Co., LTD., Yongin-si (KR)

(72) Inventors: HIROTSUGU KISHIMOTO, Yongin-si (KR); HYEONG-JUN KIM, Yongin-si (KR); SUNGGUK AN, Yongin-si (KR); JUNHO KWACK, Yongin-si (KR); KI-SIK BAN, Yongin-si (KR); SUKHO CHOI, Yongin-si (KR)

(21) Appl. No.: 18/585,202

(22) Filed: Feb. 23, 2024

(30) Foreign Application Priority Data
Aug. 28, 2023 (KR) 10-2023-0112466

(51) Int. Cl. H10K 59/131; B32B 5/02; B32B 7/12; B32B 27/12; H10K 59/40; H10K 77/10; H10K 102/00

(52) U.S. Cl. CPC H10K 59/131; B32B 5/02; B32B 7/12; B32B 27/12; H10K 59/40; H10K 77/111; B32B 2260/021; B32B 2260/046; B32B 2262/101; B32B 2307/202; B32B 2307/412; B32B 2307/42; B32B 2457/20; H10K 2102/311

(57) ABSTRACT

A display device includes a display panel including a substrate including a display area and a non-display area which is adjacent to the display area, pixels which are on the substrate, in the display area, and a pad electrode which is on the substrate, in the non-display area, a support member which overlaps the display area and the non-display area and is under the substrate of the display panel, the support member including a connecting wire which is in the non-display area, penetrates a thickness of the support member and is electrically connected to the pad electrode, and a connecting member which contacts each of the pad electrode of the display panel and the connecting wire of the support member and connects the pad electrode to the connecting wire.

This application claims priority to Korean Patent Application No. 10-2023-0112466, filed on Aug. 28, 2023, and all the benefits accruing therefrom under 35 U.S.C. § 119, which is hereby incorporated by reference for all purposes as if fully set forth herein.

### BACKGROUND

### 1. Field

Embodiments relate to a display device. More particularly, the embodiments relate to the display device having a connecting wire which is inside a support member.

### 2. Description of the Related Art

A display device is a device which displays an image to provide visual information to outside the display device, such as to a user. With the development of information technology, the importance of the display device, which is the connecting medium between users and information, is being highlighted. For example, the use of the display device such as a liquid crystal display device (LCD) and a organic light emitting display device (OLED) is increasing.

The display device may include a display area which displays the image and a non-display area which surrounds the display area. In the display area, pixels which are the smallest units to display the image may be disposed. Each of the pixels may include a pixel circuit and a light emitting element which is connected to the pixel circuit. In the non-display area, a plurality of wires and drive chips may be disposed.

### SUMMARY

Embodiments provide a display device with improved reliability and display quality.

A display device according to an embodiment includes a substrate including a display area and a non-display area adjacent to the display area, a display panel disposed on the substrate and including a plurality of pixels, a support member overlapping the display area and the non-display area and disposed under the substrate, a connecting wire overlapping a portion of the non-display area and at least a portion of which penetrates the support member, a pad electrode disposed in the non-display area on the substrate and connected electrically to the connecting wire, and a connecting member contacting each of the pad electrode and the connecting wire.

In an embodiment, in the non-display area, a contact hole may be defined in the substance and the pad electrode may penetrate the substrate and the pad electrode in a thickness direction, at the contact hole.

In an embodiment, the connecting member electrically may connect the connecting wire and the pad electrode, through the contact hole.

In an embodiment, the display device may further include a driving chip which provides signals and voltages to the plurality of pixels, and the connecting wire may include a first portion overlapping at least a portion of an upper surface of the support member and contacting the connecting member, a second portion disposed on a rear surface and contacting the driving chip, and a third portion connecting the first portion and the second portion.

In an embodiment, the display device may further include an electronic component disposed on a rear surface of the second portion.

In an embodiment, the display area may include a foldable area with flexibility and a non-folding area adjacent to the foldable area, and the support member may include a stretchable portion (e.g., a foldable portion) overlapping the foldable area and having a lattice shape, and a flat portion overlapping the non-folding area and adjacent to the stretchable portion.

In an embodiment, the first portion may be located in a direction opposite to a direction in which the third portion faces the stretchable portion and the second portion may be located in the direction in which the third portion faces the stretchable portion.

In an embodiment, the connecting member may include a conductive material.

In an embodiment, the conductive material may include a solder paste or a silver (Ag) paste.

In an embodiment, the connecting member may include an anisotropic conductive film (ACF).

In an embodiment, the support member may include glass fiber reinforced plastic (GFRP).

In an embodiment, each of the pad electrode and the connecting member may be repeatedly arranged along a direction parallel to the substrate.

A display device according to an embodiment includes a substrate including a display area and a non-display area adjacent to the display area, a display panel disposed on the substrate and including a plurality of pixels, a support member overlapping the display area and the non-display area and disposed under the substrate, a connecting wire overlapping a portion of the non-display area and at least a portion of which penetrates the support member, a pad electrode disposed in the non-display area on the substrate and connected electrically to the connecting wire, a connecting member contacting each of the pad electrode and the connecting wire, and a digitizer located in the support member and including a plurality of first wires each extending in a first direction and a plurality of second wires disposed in a different layer with the first wires and each extending in a second direction intersecting the first direction.

In an embodiment, the first wires are repeatedly arranged along the second direction and the second wires are repeatedly arranged along the first direction.

In an embodiment, the first wires are disposed under the second wires and the first wires and the second wires are connected to each other.

In an embodiment, the digitizer may further include a connector connected to each of the first wires and the second wires.

In an embodiment, the display area may include a foldable area with flexibility and non-folding area adjacent to the foldable area and the support member may include a stretchable portion overlapping the foldable area and having a lattice shape and a flat portion overlapping the non-folding area and adjacent to the stretchable portion.

In an embodiment, each of the second wires may include a first pattern overlapping the flat portion and a second pattern overlapping the stretchable portion and surrounding the lattice shape of the stretchable portion.

In an embodiment, the support member includes a top layer disposed on the second wires, a bottom layer disposed under the first wires, and a middle layer excluding the top layer and the bottom layer and the top layer and the bottom layer include a same material, and the middle layer and each of the top layer and the bottom layer includes a different material.

In an embodiment, the connecting member includes an anisotropic conductive film (ACF).

In a display device according to embodiments of the present disclosure, the display device may include a support member and a connecting wire disposed inside the support member. The first portion of the connecting wire may contact a connecting member filling a contact hole penetrating a substrate in the thickness direction, and the second portion of the connecting wire may contact a driving chip which provides signals and voltages to a plurality of pixels. Accordingly, the driving chip may be attached to the connecting wire without a separate film, and since no additional space is required to dispose the film, the dead space of the display device may be reduced. In addition, since some components of the display device connected to the driving chip may not be bent, the strength of the display device may be improved.

### BRIEF DESCRIPTION OF THE DRAWINGS

Illustrative, non-limiting embodiments will be more clearly understood from the following detailed description in conjunction with the accompanying drawings.

FIG. 1 is a plan view illustrating a display device according to an embodiment of the present disclosure.

FIG. 2 is a side view illustrating an example of the display device of FIG. 1 in a folded state.

FIG. 3 is a side view illustrating an example of the display device of FIG. 1 in a folded state.

FIG. 4 is a cross-sectional view illustrating an example of a cross-section taken along line I-I′ of FIG. 1.

FIG. 5 is an enlarged view of area A of FIG. 4.

FIG. 6 is an enlarged view of area B of FIG. 4.

FIG. 7 is a plan view illustrating an example of a first portion of the connecting wire of FIG. 4.

FIG. 8 is a plan view illustrating an example of a second portion of the connecting wire of FIG. 4.

FIG. 9 is a plan view illustrating an example of a second portion of the connecting wire of FIG. 4.

FIG. 10 is a cross-sectional view illustrating an example of a cross-section taken along line I-I′ of FIG. 1.

FIG. 11 is an enlarged view of area C of FIG. 10.

FIG. 12 is a cross-sectional view illustrating an example of a cross-section taken along line I-I′ of FIG. 1.

FIG. 13 is a plan view illustrating an example of a digitizer of FIG. 12.

FIG. 14 is an enlarged view of area D of FIG. 13.

FIG. 15 is a cross-sectional view illustrating an example of a cross-section taken along line I-I′ of FIG. 1.

### DETAILED DESCRIPTION

Hereinafter, display devices in accordance with embodiments will be described in more detail with reference to the accompanying drawings. The same reference numerals are used for the same components in the drawings, and redundant descriptions of the same components will be omitted. Within the Figures and the text of the disclosure, a reference number indicating a singular form of an element may also be used to reference a plurality of the singular element.

It will be understood that when an element is referred to as being related to another element such as being “on” another element, it can be directly on the other element or intervening elements may be present therebetween. In contrast, when an element is referred to as being related to another element such as “directly on” another element, there are no intervening elements present.

It will be understood that, although the terms “first,” “second,” “third” etc. may be used herein to describe various elements, components, regions, layers and/or sections, these elements, components, regions, layers and/or sections should not be limited by these terms. These terms are only used to distinguish one element, component, region, layer or section from another element, component, region, layer or section. Thus, “a first element,” “component,” “region,” “layer” or “section” discussed below could be termed a second element, component, region, layer or section without departing from the teachings herein.

The terminology used herein is for the purpose of describing particular embodiments only and is not intended to be limiting. As used herein, “a”, “an,” “the,” and “at least one” do not denote a limitation of quantity, and are intended to include both the singular and plural, unless the context clearly indicates otherwise. Thus, reference to “an” element in a claim followed by reference to “the” element is inclusive of one element and a plurality of the elements. For example, “an element” has the same meaning as “at least one element,” unless the context clearly indicates otherwise. “At least one” is not to be construed as limiting “a” or “an.” “Or” means “and/or.” As used herein, the term “and/or” includes any and all combinations of one or more of the associated listed items. It will be further understood that the terms “comprises” and/or “comprising,” or “includes” and/or “including” when used in this specification, specify the presence of stated features, regions, integers, steps, operations, elements, and/or components, but do not preclude the presence or addition of one or more other features, regions, integers, steps, operations, elements, components, and/or groups thereof.

Furthermore, relative terms, such as “lower” or “bottom” and “upper” or “top,” may be used herein to describe one element's relationship to another element as illustrated in the Figures. It will be understood that relative terms are intended to encompass different orientations of the device in addition to the orientation depicted in the Figures. For example, if the device in one of the figures is turned over, elements described as being on the “lower” side of other elements would then be oriented on “upper” sides of the other elements. The term “lower,” can therefore, encompasses both an orientation of “lower” and “upper,” depending on the particular orientation of the figure. Similarly, if the device in one of the figures is turned over, elements described as “below” or “beneath” other elements would then be oriented “above” the other elements. The terms “below” or “beneath” can, therefore, encompass both an orientation of above and below.

Unless otherwise defined, all terms (including technical and scientific terms) used herein have the same meaning as commonly understood by one of ordinary skill in the art to which this disclosure belongs. It will be further understood that terms, such as those defined in commonly used dictionaries, should be interpreted as having a meaning that is consistent with their meaning in the context of the relevant art and the present disclosure, and will not be interpreted in an idealized or overly formal sense unless expressly so defined herein.

Embodiments are described herein with reference to cross-section illustrations that are schematic illustrations of idealized embodiments. As such, variations from the shapes of the illustrations as a result, for example, of manufacturing techniques and/or tolerances, are to be expected. Thus, embodiments described herein should not be construed as limited to the particular shapes of regions as illustrated herein but are to include deviations in shapes that result, for example, from manufacturing. For example, a region illustrated or described as flat may, typically, have rough and/or nonlinear features. Moreover, sharp angles that are illustrated may be rounded. Thus, the regions illustrated in the figures are schematic in nature and their shapes are not intended to illustrate the precise shape of a region and are not intended to limit the scope of the present claims.

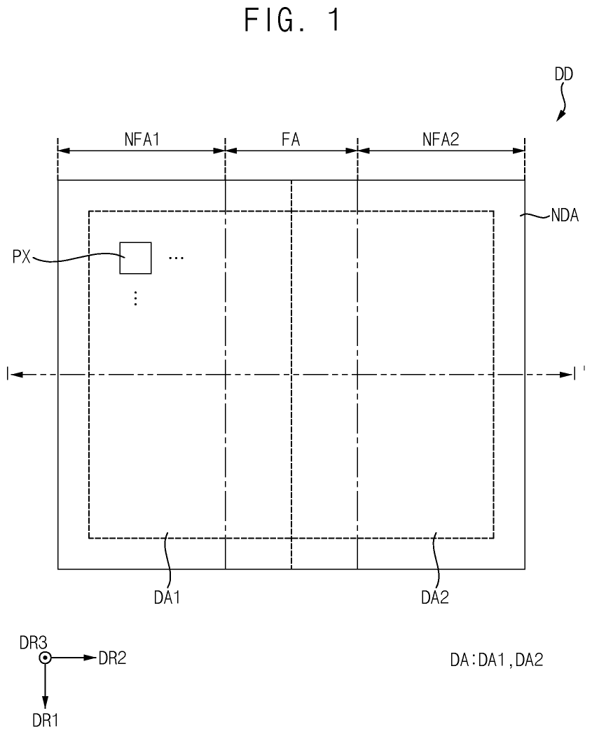

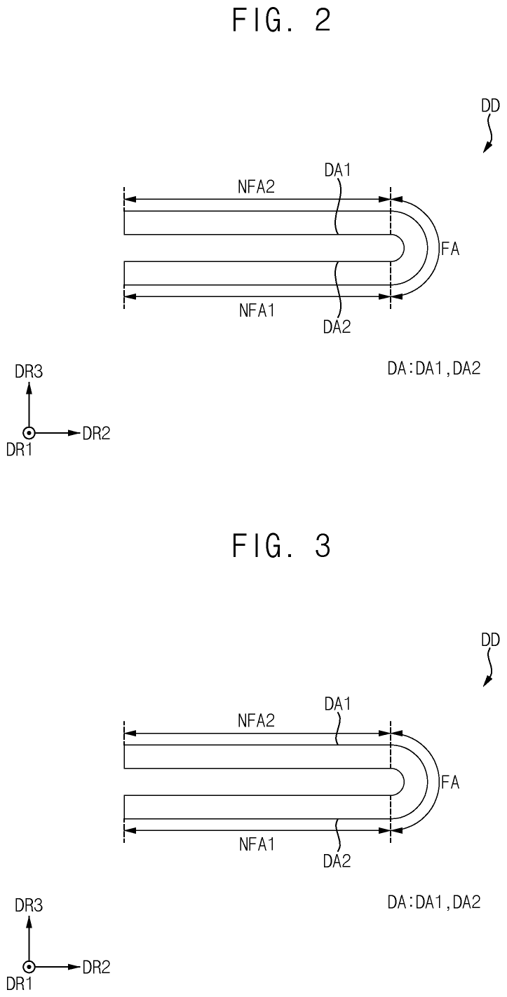

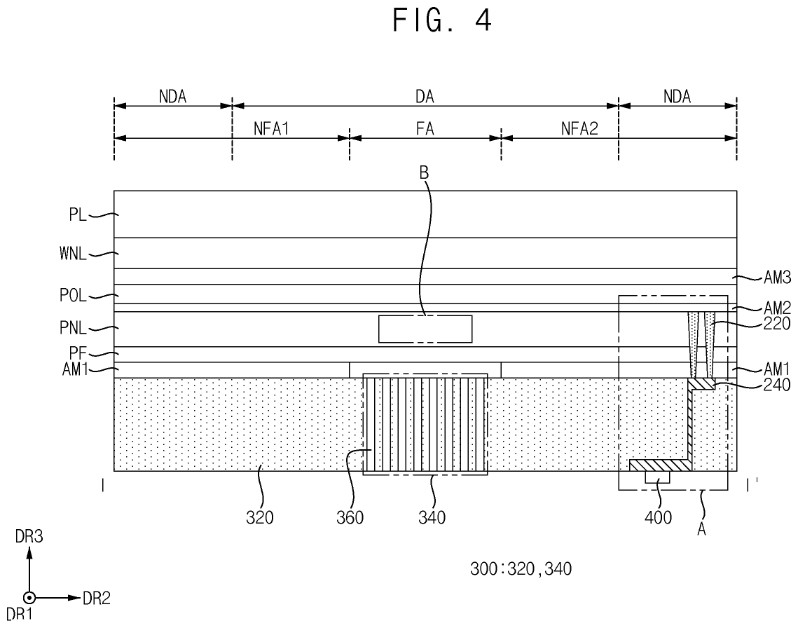

FIG. 1 is a plan view illustrating a display device DD according to an embodiment of the present disclosure. FIG. 2 is a side view illustrating an example of the display device DD of FIG. 1 in a folded state. FIG. 3 is a side view illustrating an example of the display device DD of FIG. 1 in a folded state.

Referring to FIGS. 1, 2, and 3, a display device DD may include a display area DA and a non-display area NDA. The display area DA may be defined as an area (e.g., a planar area) which generates an image, and the non-display area NDA may be defined as an area which does not generate an image. The non-display area NDA may be located adjacent to the display area DA. For example, the non-display area NDA may entirely surround the display area DA (e.g., extend along an entirety of the display area DA).

In this specification, a plane may be defined by a first direction DR1 and a second direction DR2 crossing each other. For example, the second direction DR2 may be perpendicular to the first direction DR1. In addition, the third direction DR3 may be perpendicular to the plane. A thickness of the display device DD and various components or layers thereof may be defined along the third direction.

A plurality of pixels PX may be arranged in the display area DA. For example, the pixels PX may be entirely arranged in the display area DA along the first direction DR1 and the second direction DR2. Each of the pixels PX may emit light having a predetermined color. An image may be displayed in the display area DA by the light emitted from each of the pixels PX.

The display device DD may include a foldable area FA at which the display device DD may be bent such as by an external force so that the display device DD may be folded, and first and second non-folding areas NFA1 and NFA2 at which the display device DD may not be folded. A non-folding area may be adjacent to at least one side of the foldable area FA. The non-folding area may remain flat even in the display device DD which is folded at the foldable area FA. The foldable area FA and the first and second non-folding areas NFA1 and NFA2 may at least overlap the display area DA. For example, the foldable area FA may include a folding axis extending along the first direction DR1 and about which the display device DD is foldable. Various components or layers may include a display area DA, a non-display area NDA, a foldable area FA, a non-folding area, etc. corresponding to those described above. More than one among the components and layers may be foldable, bendable, etc. together with each other, such as at the foldable area FA.

The display area DA may be divided into a first display area DA1 and a second display area DA2 adjacent to each other along the second direction DR2 which intersects the first direction DR1. For example, the second direction DR2 may intersect the first direction DR1. The first display area DA1 and the second display area DA2 may be continuously connected to substantially form one display area DA. For example, when the display device DD is folded along the folding axis, the display device DD may have an in-folding structure where the first display area DA1 and the second display area DA2 face each other, as shown in FIG. 2. Alternatively, as shown in FIG. 3, when the display device DD is folded along the folding axis, the display device DD may have an out-folding structure in which the display area DA is disposed on the outside and portions of the display area DA face in directions opposite to each other.

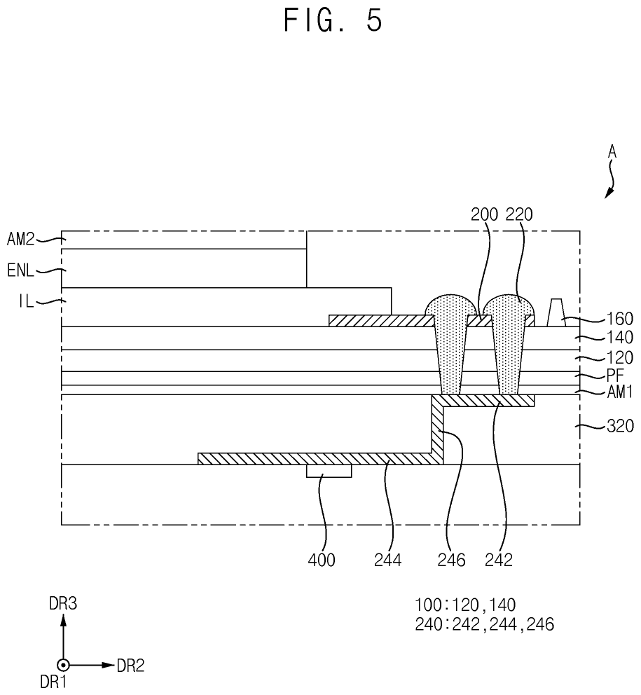

FIG. 4 is a cross-sectional view illustrating an example of a cross-section taken along line I-I′ of FIG. 1. FIG. 5 is an enlarged view of area A of FIG. 4. For example, FIG. 5 is an enlarged view of a portion of the non-display area NDA where a connecting wire 240 in FIG. 4 is disposed.

Referring to FIGS. 4 and 5, the display device DD may include a display panel PNL, a pad electrode 200, a connecting member 220, a support member 300, a protective film PF, a connecting wire 240, a driving chip 400, a polarizing member POL, a window member WNL, a protective layer PL, a first adhesive member AM1, a second adhesive member AM2, and a third adhesive member AM3.

The display panel PNL may include a first substrate layer 120, a second substrate layer 140, a crack prevention dam 160, an insulating layer IL, and an encapsulation layer ENL, in the non-display area NDA. A substrate 100 may include the first substrate layer 120 and the second substrate layer 140.

The first substrate layer 120 may be a transparent insulating substrate. The first substrate layer 120 may be flexible to allow bending. Examples of materials which may be used as the first substrate layer 120 include a polyimide (PI), a polyethersulfone (PES), a polyacrylate (PAR), a polyetherimide (PEI), a polyethylene naphthalate (PEN), a polyethylene terephthalate (PET), a polyphenylene sulfide (PPS), a polycarbonate (PC), a cellulose acetate propionate (CAP), and the like. These may be used alone or in combination with each other.

The second substrate layer 140 may be disposed on top of the first substrate layer 120. The second substrate layer 140 may include substantially a same material as the first substrate layer 120.

The crack prevention dam 160 may be disposed on the non-display area NDA of the second substrate layer 140. The crack prevention dam 160 may be located closer to a outermost edge of the display device DD (that is, the outermost edge of the non-display area NDA) than a pad electrode 200. For example, the crack prevention dam 160 may be located in the second direction DR2 relative to the pad electrode 200, to be closer to the outermost edge than the pad electrode 200. Specifically, the crack prevention dam 160 may be spaced apart from the pad electrode 200 along the second substrate layer 140, in the second direction DR2.

The crack prevention dam 160 may include an inorganic insulating material. For example, the inorganic insulating material may include a silicon nitride (SiNx), a silicon oxide (SiOx), a silicon oxynitride (SiOxNy), and the like. These may be used alone or in combination with each other.

The insulating layer IL may be disposed on the display area DA of the second substrate layer 140. The insulating layer IL may include a multilayer structure. The insulating layer IL may be disposed in a same layer as the crack prevention dam 160. The insulating layer IL may include substantially a same material as the crack prevention dam 160. In addition, the insulating layer IL may be formed through substantially a same process as the crack prevention dam 160. However, the present disclosure may not be limited to this. As being in a same layer, elements may be formed in a same process and/or include a same material as each other, elements may be respective portions of a same material layer, elements may be on a same layer by forming an interface with a same underlying or overlying layer, etc., without being limited thereto.

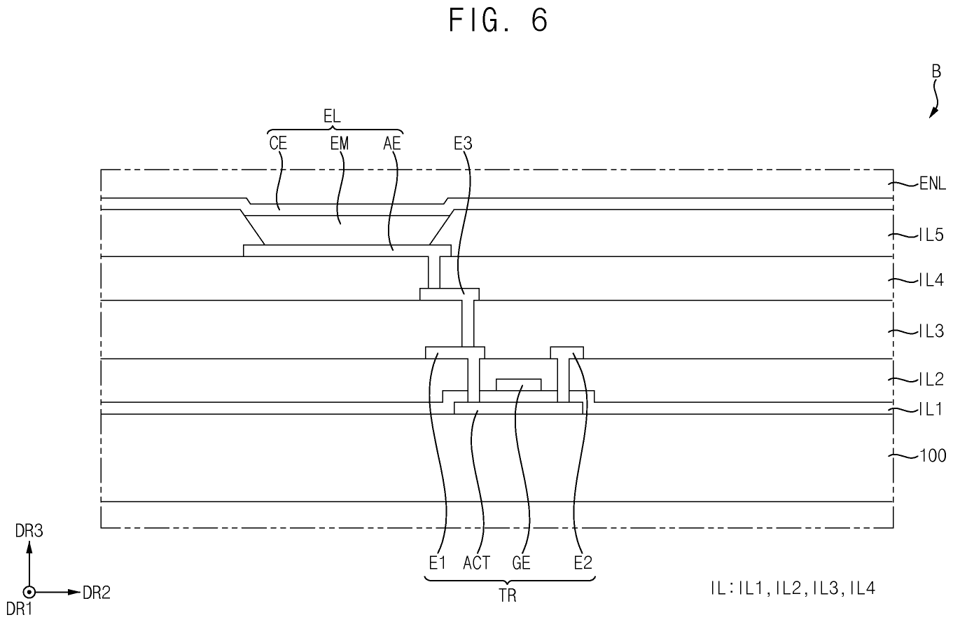

The encapsulation layer ENL may be disposed on the insulating layer IL. For example, the encapsulation layer ENL may cover the top of the insulating layer IL. An explanation about the encapsulation layer ENL will be described in detail later with reference to FIG. 6.

The pad electrode 200 may be disposed on the non-display area NDA, on the second substrate layer 140. The pad electrode 200 may be electrically connected to an external device (not shown). Specifically, the external device may provide a data signal, gate signal, emission control signal, gate initialization signal, initialization voltage, and power voltage to the pixels PX. That is, the pad electrode 200 may electrically connect the external devices and the pixels PX. The external device may be connected to the display panel PNL at the pad electrode 200.

In an embodiment, a contact hole may be defined which simultaneously penetrates the substrate 100 and the pad electrode 200 in the third direction DR3. The contact hole may be formed (or provided) by removing a material portion of each of the pad electrode 200, the first substrate layer 120, and the second substrate layer 140. In an embodiment, the substrate 100 defines a contact hole of the substrate 100, in the non-display area NDA, and the connecting member 220 penetrates through a thickness of the pad electrode 200 and further penetrates through a thickness of the substrate 100, at the contact hole. Here, the connecting wire 240 of the support member 300 is exposed to outside the substrate 100 at the contact hole, and the connecting member 220 electrically connects the connecting wire 240 of the support member 300 and the pad electrode 200 of the display panel PNL, at the contact hole.

The protective film PF may be disposed under the first substrate layer 120. The protective film PF may reduce stress applied to the display panel PNL when the display panel PNL is folded or bent. In addition, the protective film PF may prevent moisture from penetrating into the display panel PNL and/or absorb external shocks.

The protective film PF may include a polymer material. For example, the polymer material may include a polyimide (PI), a polyethylene terephthalate (PET), a polycarbonate (PC), a polyethylene (PE), a polypropylene (PP), a polysulfonc (PSF), and a polymethyl methacrylate (PMMA), a triacetyl cellulose (TAC), a cycloolefin polymer (COP), and the like. These may be used alone or in combination with each other.

The connecting member 220 may contact the pad electrode 200. As being in contact, elements which are in physical contact with each other may form an interface therebetween. In an embodiment, the connecting member 220 may electrically connect the pad electrode 200 and the connecting wire 240 to each other, at or through the contact hole. For example, the connecting member 220 may fill the contact hole which simultaneously penetrates the substrate 100 and the pad electrode 200, such that the contact hole is completely filled with the material of the connecting member 220. Specifically, the contact hole may extend to the protective film PF and the first adhesive member AM1, to expose side surfaces of these layers to outside the stacked structure. Here, the connecting member 220 may penetrate through a thickness of the pad electrode 200, the substrate 100, the protective film PF, and the first adhesive member AM1. The connecting wire 240 may be exposed to outside the stacked structure at the contact hole.

Each connecting member 220 among plural connecting members 220 may penetrate a same one of the pad electrodes 200, to define more than one contact area between a single pad electrode 200 and a plurality of connecting members 220. Similarly, more than one contact area may be defined between a single connecting wire 240 and a plurality of connecting members 220.

Referring to FIG. 5, the connecting member 220 and the pad electrode 200 may be exposed to outside the display panel PNL, in the non-display area NDA. One or more layers of the display panel PNL may extend further than other layers, to define an extended portion (or exposed portion) at the non-display area NDA. In FIG. 5, for example, the first substrate layer 120 and the second substrate layer 140 extend further than an end surface of the insulating layer IL and/or the second adhesive member AM2, to define an extended portion of the display panel PNL at which the connecting member 220 and the pad electrode 200 are exposed to outside the display panel PNL, An opening or recess may be defined in an insulating material layer (e.g., insulating layer IL and the crack prevention dam 160), and the connecting member 220, the pad electrode 200 and the second substrate layer 140 may be exposed to outside the display panel PNL at the opening.

In an embodiment, the connecting member 220 may include a conductive material (e.g., an electrically conductive material). For example, the conductive material may include solder paste, silver (Ag) paste, and the like. These may be used alone or in combination with each other.

The support member 300 may be disposed under the protective film PF. The support member 300 may include a flat portion 320 located in the first and second non-folding areas NFA1 and NFA2, and a stretchable portion 340 overlapping the foldable area FA. The stretchable portion 340 may have elasticity in response to folding and unfolding of the display device DD, such as defining a deformable portion or foldable portion of the support member 300. In other words, the flat portion 320 may be a portion of the support member 300 which corresponds to the first and second non-folding areas NFA1 and NFA2. In addition, the stretchable portion 340 may be a portion of the support member 300 which corresponds to the foldable area FA. Here, the support member 300 includes the foldable portion overlapping the foldable area FA of the display area DA and having a lattice shape and the flat portion 320 which overlaps the non-folding area of the display area DA and is adjacent to the foldable portion.

In an embodiment, the support member 300 may include a glass fiber reinforced plastic (GFRP), a carbon fiber rein forced plastic (CFRP), and the like. These may be used alone or in combination with each other.

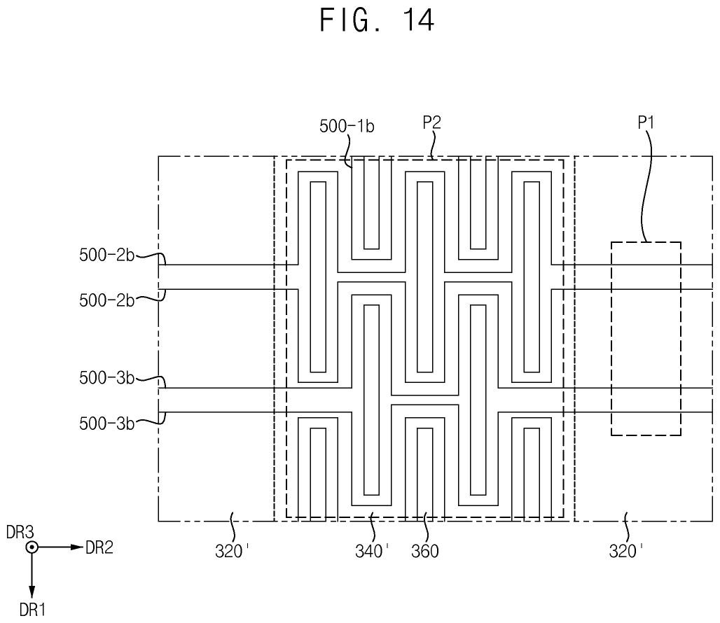

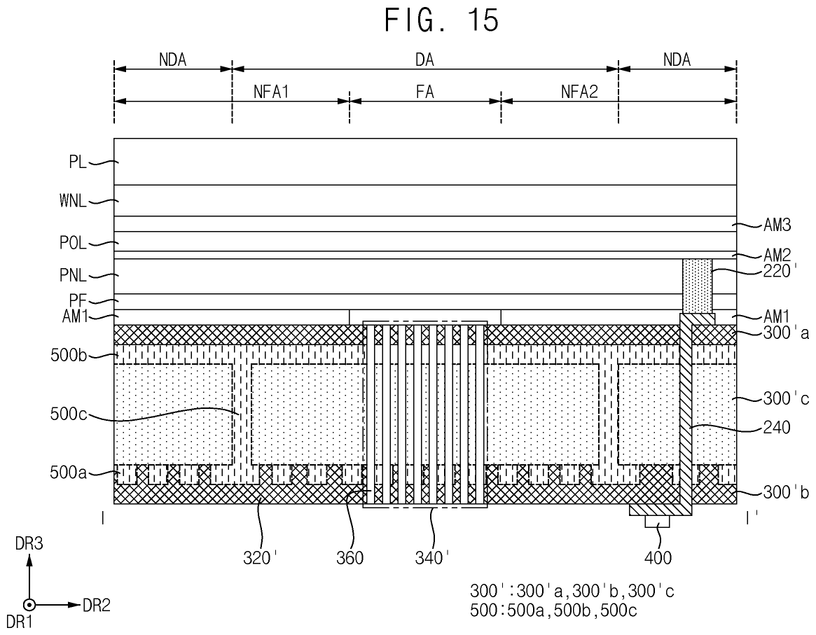

In an embodiment, the stretchable portion 340 may have a lattice shape in the plan view (e.g., a view of the DR1-DR2 plane). Specifically, a plurality of holes 360 may be defined along a thickness of the support member 300, in the stretchable portion 340. An explanation of the plurality of holes 360 will be described later with reference to FIG. 14.

The first adhesive member AM1 may be disposed between the support member 300 and the protective film PF. For example, the first adhesive member AM1 may attach the protective film PF to the support member 300. The first adhesive member AM1 may include an optical clear adhesive (OCA), a pressure sensitive adhesive (PSA), a photocurable resin, a thermosetting resin, and the like. These may be used alone or in combination with each other.

The first adhesive member AM1 may be disposed on the flat portion 320 of the support member 300. However, the first adhesive member AM1 may not be disposed on the stretchable portion 340. That is, the first adhesive member AM1 may be disconnected or separated along the support member 300, at an area corresponding to the foldable area FA.

The connecting wire 240 may be disposed on the non-display area NDA. In addition, the connecting wire 240 may be disposed to penetrate the flat portion 320 which overlaps the non-display area NDA. The connecting wire 240 may include a first portion 242, a second portion 244, and a third portion 246.

The first portion 242 may be a portion of the connecting wire 240 which faces the third direction DR3. In an embodiment, first portion 242 may contact connecting member 220. That is, the connecting wire 240 may be electrically connected to the connecting member 220 at the first portion 242. The first portion 242 may be adjacent to (or closest to) an upper surface of the flat portion 320, where the upper surface is closest to the display panel PNL along the thickness direction. For example, the first portion 242 may contact the connecting member 220 by the first portion 242 defining an exposed surface at the flat portion 320.

In an embodiment, one surface of the first portion 242 may be located in a same plane as the upper surface of the flat portion 320. That is, the upper surface of the connecting wire 240 at the first portion 242 thereof, and the upper surface of the support member 300 at the flat portion 320 thereof, may be coplanar with each other. In an embodiment, the one surface of the first portion 242 may not be located in a same plane as the upper surface of the flat portion 320.

The second portion 244 may face a direction opposite to the third direction DR3 of the connecting wire 240 and may be a different (planar) portion from the first portion 242. In an embodiment, the second portion 244 may contact the driving chip 400. That is, the connecting wire 240 may be electrically connected to the driving chip 400 at the second portion 244. The second portion 244 may be adjacent to a rear surface of the flat portion 320 which is furthest from the display panel PNL. For example, the second portion 244 may contact the driving chip 400 by exposing the rear surface of the flat portion 320. Accordingly, an electrical signal generated from the driving chip 400 may be transmitted to the pixels PX, through the pad electrode 200, the connecting member 220, and the connecting wire 240.

In an embodiment, one surface of the second portion 244 may be located in a same plane as (e.g., coplanar with) the rear surface of the flat portion 320. In an embodiment, the one surface of the second portion 244 may not be located in a same plane as the rear surface of the flat portion 320.

The third portion 246 may connect the first portion 242 and the second portion 244 to each other. Accordingly, the first portion 242 and the second portion 244 may be positioned adjacent to the upper and rear surfaces of the flat portion 320, respectively. The third portion 246 may be located inside the support member 300. For example, the third portion 246 may penetrate the support member 300 in the third direction DR3, to be inside a thickness of the support member 300.

The third portion 246 may be perpendicular to each of the first portion 242 and the second portion 244. In addition, the first portion 242, the second portion 244, and the third portion 246 may together have a stepped shape. In an embodiment, in a direction along the support member 300 (e.g., along the DR1-DR2 plane, for example), the first portion 242 of the connecting wire 240 extends from the third portion 246, in a direction away from the foldable portion, and the second portion 244 of the connecting wire 240 extends from the third portion 246, in a direction towards the foldable portion. However, the present disclosure may not be limited to this, and the connecting wire 240 may have various shapes which contact the connecting member 220 and the driving chip 400.

The driving chip 400 may be disposed under the connecting wire 240. For example, the driving chip 400 may contact the second portion 244 which is exposed at the rear surface of the flat portion 320. Specifically, the driving chip 400 may contact the second portion 244, and a film may not be disposed between the driving chip 400 and the second portion 244. That is, the driving chip 400 and the second portion 244 may form an interface therebetween. In an embodiment, the driving chip 400 provides signals and voltages to the pixels PX. The support member includes an upper surface and a rear surface which is opposite to the upper surface along the thickness of the support member 300 (e.g., along the third direction DR3). The connecting wire 240 which is in the non-display area NDA includes the first portion 242 contacting the connecting member 220 at the upper surface of the support member 300, the second portion 244 contacting the driving chip 400 at the rear surface of the support member 300 and the third portion 246 connecting the first portion 242 and the second portion 244 to each other.

As described above, the connecting wire 240 may be located inside the support member 300. In addition, the connecting wire 240 may directly contact the connecting member 220 and the driving chip 400. Accordingly, the driving chip 400 may contact the connecting wire 240 without a separate film, and since no additional space is required for the film to be disposed, a dead space of the display device DD may be reduced. In addition, since some components of the display device DD connected to the driving chip 400 may not be bent, the strength of the display device DD may be improved.

The polarizing member POL may be disposed on the display panel PNL. The polarizing member POL may block external light incident on the display panel PNL from the outside.

The second adhesive member AM2 may be disposed between the polarizing member POL and the display panel PNL. For example, the second adhesive member AM2 may be disposed between the polarizing member POL and the encapsulation layer ENL. The second adhesive member AM2 may include substantially a same material as the first adhesive member AM1.

The window member WNL may be disposed on the polarizing member POL. The window member WNL may have a transparent portion or light transmitting portion corresponding to the display area DA. For example, the window member WNL may include a polymer material, a glass thin film, and the like which are bendable. These may be used alone or in combination with each other.

The third adhesive member AM3 may be disposed between the window member WNL and the polarizing member POL. For example, the third adhesive member AM3 may attach the window member WNL and the polarizing member POL to each other. The third adhesive member AM3 may include substantially a same material as the second adhesive member AM2.

The protective layer PL may be disposed on the window member WNL. The protective layer PL may perform at least one function among preventing the window member WNL which is broken from scattering, preventing the window member WNL from being scratched, preventing glare and/or fingerprints at a front surface of the display device DD, and absorbing shocks to prevent the shocks from being transferred to the window member WNL. The protective layer PL may include a transparent polymer film. For example, examples of the transparent polymer film constituting the protective layer PL include a polyethylene terephthalate (PET), a polyethylene naphthalate (PEN), a polyethersulfone (PES), a polyimide (PI), and a polyarylate (PAR), a polycarbonate (PC), a polymethyl methacrylate (PMMA), a cycloolefin polymer (COP), and the like. These may be used alone or in combination with each other.

FIG. 6 is an enlarged view of area B of FIG. 4.

Referring to FIGS. 4, 5, and 6, the display panel PNL may include the substrate 100, an active pattern ACT, a first insulating layer IL1, a gate electrode GE, a second insulating layer IL2, an electrode layer including a first electrode E1 and a second electrode E2, a third insulating layer IL3, a third electrode E3, a fourth insulating layer IL4, a pixel electrode AE, a light emitting layer EM, a fifth insulating layer IL5, a common electrode CE, and an encapsulation layer ENL.

The insulating layer IL may be disposed on the display area DA of the substrate 100. The insulating layer IL may include the first insulating layer IL1, the second insulating layer IL2, the third insulating layer IL3, and the fourth insulating layer IL4.

A buffer layer (not shown) may be disposed on the substrate 100. For example, the buffer layer may be disposed between the substrate 100 and the first insulating layer IL1. The buffer layer may prevent impurities from diffusing from the substrate 100 to the active pattern ACT.

The active pattern ACT may be disposed on the buffer layer. The active pattern ACT may include amorphous silicon, polycrystalline silicon, or an oxide semiconductor. The active pattern ACT may include a source region and a drain region doped with impurities, and a channel region disposed between the source region and the drain region.

The first insulating layer IL1 may be disposed on the buffer layer. The first insulating layer IL1 may cover the active pattern ACT on the buffer layer. For example, the first insulating layer IL1 may have a substantially uniform thickness along the profile of the active pattern ACT. Alternatively, the first insulating layer IL1 may sufficiently cover the active pattern ACT and may have a substantially flat upper surface without creating a step around the active pattern ACT.

The first insulating layer IL1 may include an inorganic insulating material. The inorganic insulating material may include a silicon nitride (SiNx), a silicon oxide (SiOx), a silicon oxynitride (SiOxNy), and the like. These may be used alone or in combination.

The gate electrode GE may be disposed on the first insulating layer IL1. The gate electrode GE may overlap the channel area of the active pattern ACT. The gate electrode GE may include metal, alloy, conductive metal oxide, conductive metal nitride, transparent conductive material, and the like. For example, the gate electrode GE may include a silver (Ag), an alloy containing silver, molybdenum (Mo), an alloy containing a molybdenum, aluminum (Al), an alloy containing aluminum, an aluminum nitride (AlN), a tungsten (W), a tungsten nitride (WN), a copper (Cu), a nickel (Ni), a chromium (Cr), a chromium nitride (CrN), a titanium (Ti), tatantalum (Ta), a platinum (Pt), a scandium (Sc), an indium tin oxide (ITO), and an indium zinc oxide (IZO) and the like. These may be used alone or in combination with each other.

The second insulating layer IL2 may be disposed on the first insulating layer IL1. The second insulating layer IL2 may cover the gate electrode GE. The second insulating layer IL2 may include an inorganic insulating material.

The second insulating layer IL2 may include an inorganic insulating material. The inorganic insulating material may include a silicon nitride (SiNx), a silicon oxide (SiOx), a silicon oxynitride (SiOxNy), and the like. These may be used alone or in combination.

The first electrode E1 and the second electrode E2 may be disposed on the second insulating layer IL2. The first electrode E1 and the second electrode E2 may be connected to the source region and the drain region of the active pattern ACT, respectively, through contact holes penetrating the first insulating layer IL1 and the second insulating layer IL2. The first electrode E1 and the second electrode E2 may include a metal, an alloy, a conductive metal oxide, a conductive metal nitride, a transparent conductive material, and the like. The active pattern ACT, gate electrode GE, first electrode E1, and second electrode E2 may form a transistor TR.

The third insulating layer IL3 may be disposed on the second insulating layer IL2. The third insulating layer IL3 may cover the first electrode E1 and the second electrode E2. The third insulating layer IL3 may include an organic insulating material. The organic insulating material may include a photoresist, a polyacryl-based region, a polyimide-based resin, a polyamide-based resin, a polyamide-based resin, a siloxane-based resin, a acryl-based resin, an epoxy-based resin, and the like. These may be used alone or in combination with each other.

The third electrode E3 may be disposed on the third insulating layer IL3. The third electrode E3 may be connected to the first electrode E1 through a contact hole penetrating the third insulating layer IL3. However, the present disclosure may not be necessarily limited to this. For example, the third electrode E3 may contact the second electrode E2 through a contact hole penetrating the third insulating layer IL3. The third electrode E3 may include a metal, an alloy, a conductive metal oxide, a conductive metal nitride, a transparent conductive material, and the like.

In an embodiment, the third electrode E3 and the pad electrode 200 may be disposed in a same layer as each other. In other words, the third electrode E3 and the pad electrode 200 may be formed in a same process step. In other words, the third electrode E3 and the pad electrode 200 may include a same material. However, the present disclosure may not be necessarily limited to this, and the pad electrode 200 may be disposed in a same layer as one of various conductive material layers included in the display panel PNL.

The fourth insulating layer IL4 may be disposed on the third insulating layer IL3. The fourth insulating layer IL4 may cover the third electrode E3. The fourth insulating layer IL4 may include an organic insulating material. The organic insulating material include a photoresist, a polyacryl-based region, a polyimide-based resin, a polyamide-based resin, a siloxane-based resin, an acryl-based resin, an epoxy-based resin, and the like. These may be used alone or in combination with each other.

The pixel electrode AE may be disposed on the fourth insulating layer IL4. The pixel electrode AE may contact the first electrode E1 or the second electrode E2 through a contact hole penetrating the fourth insulating layer IL4. Accordingly, the pixel electrode AE may be electrically connected to the transistor TR.

The fifth insulating layer IL5 may be disposed on the fourth insulating layer IL4. The fifth insulating layer IL5 may partially cover the pixel electrode AE on the fourth insulating layer IL4. The fifth insulating layer IL5 may have or define a pixel opening which exposes at least a portion of an upper surface of the pixel electrode AE to outside the fifth insulating layer IL5. The fifth insulating layer IL5 may include an organic insulating material. For example, the organic insulating material may include a photoresist, a polyacryl-based region, a polyimide-based resin, a polyamide-based resin, a siloxane-based resin, a acryl-based resin, an epoxy-based resin, and the like. These may be used alone or in combination with each other.

The light emitting layer EM may be disposed on the pixel electrode AE, within the pixel opening of the a pixel defining layer (e.g., the fifth insulating layer IL5). For example, the light emitting layer EM may be disposed on the pixel electrode AE exposed to outside the fifth insulating layer IL5. In an embodiment, the light emitting layer EM may have a multilayer structure including a hole injection layer, a hole transport layer, an organic light emitting layer, an electron transport layer, and an electron injection layer.

The common electrode CE may be disposed on the light emitting layer EM and the fifth insulating layer IL5. The common electrode CE may extend from the pixel opening and along the fifth insulating layer IL5. The light emitting layer EM may emit light based on the voltage difference between the pixel electrode AE and the common electrode CE. A light emitting element EL may be formed by the pixel electrode AE, the light emitting layer EM, and the common electrode CE.

The encapsulation layer ENL may be disposed on the light emitting element EL. For example, the encapsulation layer ENL may be disposed on the common electrode CE. The encapsulation layer ENL may include at least one inorganic encapsulation layer and at least one organic encapsulation layer. The encapsulation layer ENL may prevent oxygen and moisture from penetrating into the light emitting element EL.

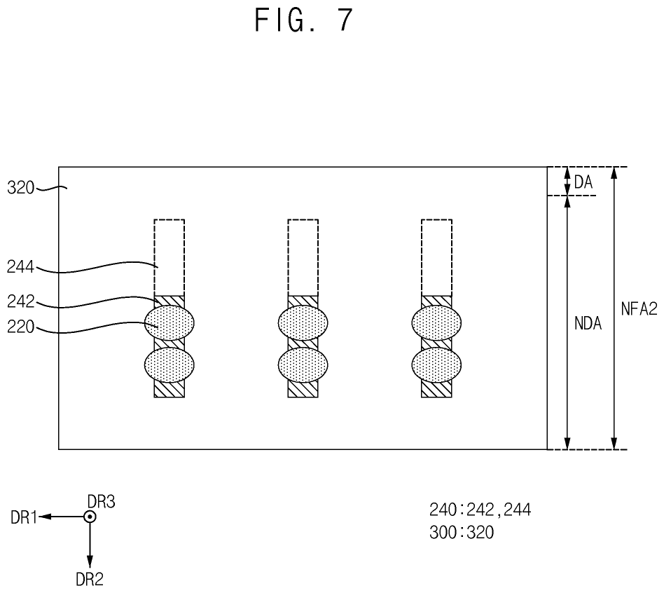

FIG. 7 is a plan view illustrating an example of a first portion 242 of the connecting wire 240 of FIG. 4, relative to an upper surface of the support member 300. Here layers other than the connecting member 220 which are above the support member 300, are omitted for illustration purposes.

Referring to the FIG. 7, in an embodiment, a planar shape of the connecting member 220 which contacts the connecting wire 240 at the first portion 242 may have a circular shape. However, the present disclosure may not be limited to this, and the planar shape of the connecting member 220 may have various shapes.

At least one connecting member 220 may contact the connecting wire 240 at the first portion 242. In an embodiment, the two or more connecting members 220 may be arranged along the second direction DR2, such as relating to a pad electrode 200 and a connecting wire 240 shown in FIG. 5.

In addition, the connecting wires 240 may be arranged along the first direction DR1, such as along an end surface of the display device DD which is defined by the non-display area NDA. However, in the present disclosure, the arrangement direction of the connecting member 220 and the connecting wire 240 may not be limited to this. Here, it will be understood that the structure in FIG. 7 represents a connecting wire 240 together with a plurality of connecting members 220 and a pad electrode 200 which correspond to the connecting wire 240. That is, pad electrodes 200 (plural) and connecting members 220 (plural) may also be arranged along the first direction DR1, to variously correspond to the connecting wires 240 which are arranged along the first direction DR1. In an embodiment, along the substrate 100, the display area DA and the non-display area NDA are adjacent to each other along one direction (e.g., the second direction DR2), and the connecting member 220 and the pad electrode 200 which is connected to the connecting member 220, are provided in plural including connecting members 220 and pad electrodes 200 arranged along a direction (e.g., the first direction DR1) crossing the one direction.

The connecting wire 240 may be disposed on (or in) the non-display area NDA. For example, the first portion 242, the second portion 244, and the third portion 246 may all be disposed on the non-display area NDA. In an embodiment, the first portion 242 may be located adjacent to or extended from the third portion 246, in the second direction DR2. In addition, in an embodiment, the second portion 244 may be located or extend in a direction opposite to the second direction DR2, relative to the third portion 246.

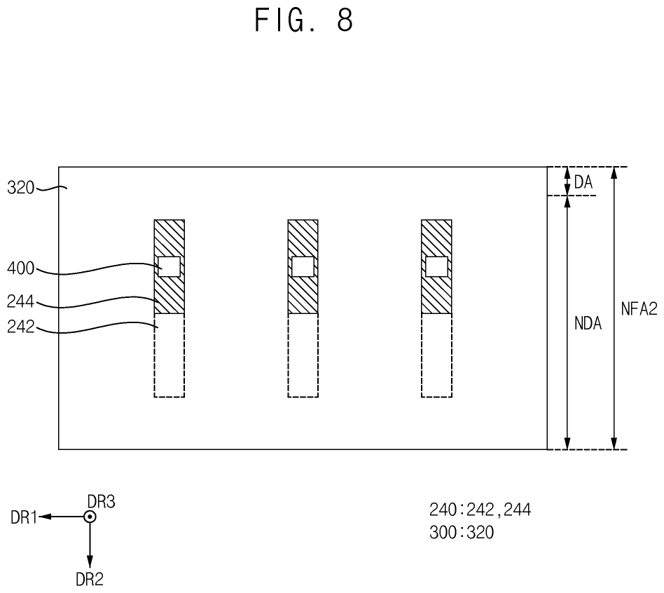

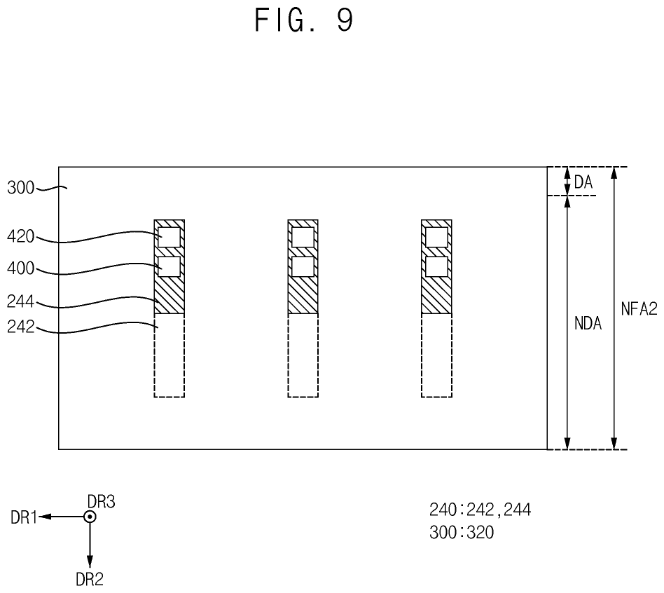

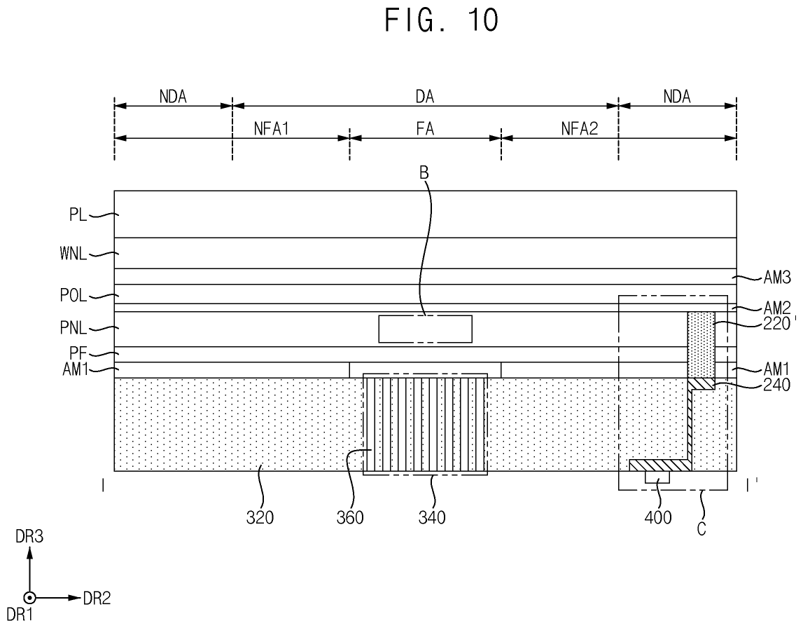

FIG. 8 is a plan view illustrating an example of a second portion 244 of the connecting wire 240 of FIG. 4. FIG. 9 is a plan view illustrating an example of a second portion 244 of the connecting wire 240 of FIG. 4. FIGS. 8 and 9 illustrate a rear (or lower) surface of the support member 300 at the flat area 320 thereof. The second portion 244 is exposed to outside the support member 300 at the rear surface thereof, while the first portion 242 is exposed to outside the support member at the front surface thereof (FIG. 7).

Referring to FIG. 8, as described above, the connecting wire 240 may contact the driving chip 400 at the second portion 244. As a plurality of connecting wires 240 are disposed, a plurality of driving chips 400 may also be disposed correspondingly.

Referring to FIG. 9, in an embodiment, the display device DD may further include an electronic component 420 disposed on the back of the second portion 244, that is, a rear surface of the connecting wire 240. For example, the electronic component 420 may contact a surface of the second portion 244, such as to be electrically connected to the connecting wire 240 at the second portion 244. In addition, the electronic component 420 may be spaced apart from the driving chip 400 in a direction opposite to the second direction DR2. However, in the present disclosure, the direction in which the driving chip 400 and the electronic component 420 are spaced apart or arranged may not be limited to the embodiment.

The electronic component 420 may provide signals and voltage and/or store information within the display device DD. The electronic components 420 may include a DC-DC converter, an application specific integrated circuit (ASIC), a low drop-out regulator (LDO regulator), an electrically erasable programmable read-only memory (EEPROM), and a flash memory. However, the present disclosure may not be limited to this and may further include various components related to driving the display device DD. In an embodiment, the electronic component 420 is adjacent to the driving chip 400 and contacts the second portion 244 of the connecting wire 240 at the rear surface of the support member 300.

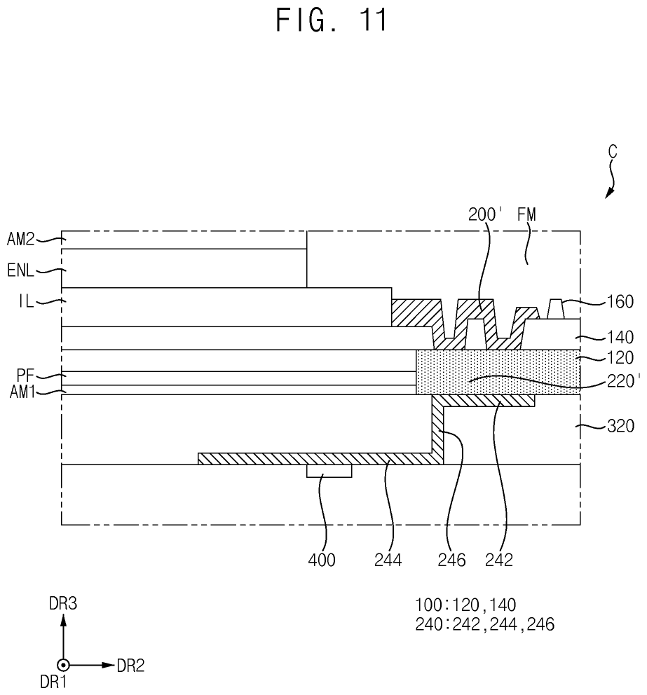

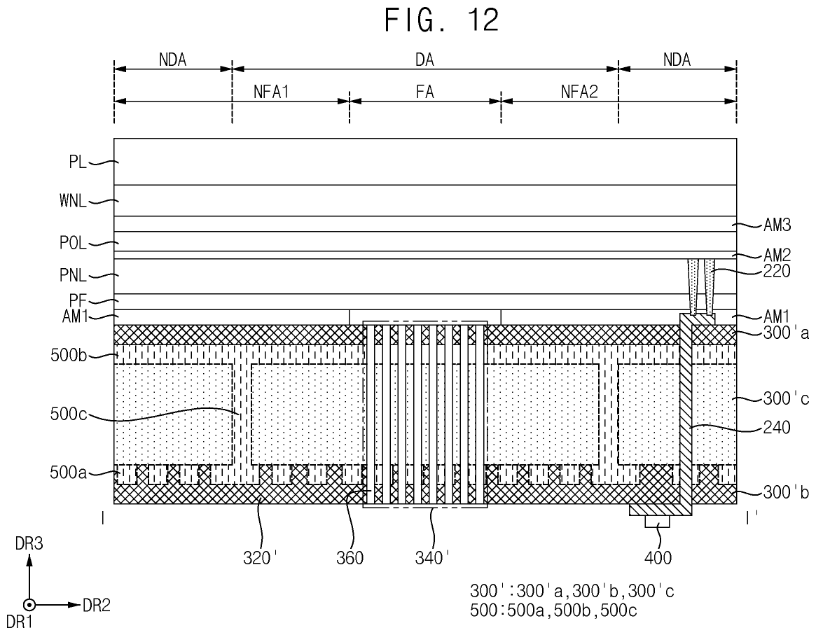

FIG. 10 is a cross-sectional view illustrating an example of a cross-section taken along line I-I′ of FIG. 1. FIG. 11 is an enlarged view of area C of FIG. 10.

Hereinafter, a content which overlaps with the a content described with reference to FIGS. 4 to 6 will be omitted or simplified.

Referring to FIGS. 10 and 11, in an embodiment, a connecting member 220′ may include an anisotropic conductive film (ACF). The connecting member 220′ may penetrate each of the substrate 100 and the protective film PF in the third direction DR3. Accordingly, the connecting member 220′ may contact each of the first portion 242 and a pad electrode 200′, at opposing surfaces of the connecting member 220′. In other words, the connecting member 220′ may electrically connect the pad electrode 200′ and the connecting wire 240 to each other. Here, the connecting member 220′ together with the connecting wire 240 may form a connecting

The pad electrode 200′ may be disposed on the second substrate layer 140. For example, the pad electrode 200′ may contact the connecting member 220′ through an opening defined in the second substrate layer 140. Accordingly, the pad electrode 200′ may contact the connecting member 220′ through one or more opening defined in the display panel PNL.

In an embodiment, the pad electrode 200′ may have a concave-convex structure along the second direction DR2. However, the present disclosure may not be limited to this, and may have various structures in which the pad electrode 200′ and the connecting member 220′ contact each other.

Referring to FIG. 11, the connecting member 220′ may be a single body instead of a plurality of members spaced apart along the second direction DR2. A single one of the pad electrodes 200′ which penetrates the display panel PNL at more than one opening therein, may contact the single body of the connecting member 220′ to define contact areas between the pad electrode 200′ and the connecting member 220′.

A filling member FM may be disposed between the pad electrode 200′ exposed to outside the display panel PNL, and the encapsulation layer ENL. The filling member FM may cover a step formed by lower layers extended further than upper layer to define extended portions, by filling an area or volume between the pad electrode 200′ and the encapsulation layer ENL. The filling member FM may contact the pad electrode 200′. For example, the filling member FM may cover the pad electrode 200′. In an embodiment, the filling member FM may include an organic material.

As described above, the driving chip 400 may be disposed on the second portion 244 of the connecting wire 240. Although not shown in FIG. 11, the driving chip 400 and the electronic component 420 (in FIG. 9) may both be disposed on the second portion 244 of the connecting wire 240. A location, and a configuration of the electronic components 420 may be substantially a same as those described with reference to FIG. 9.

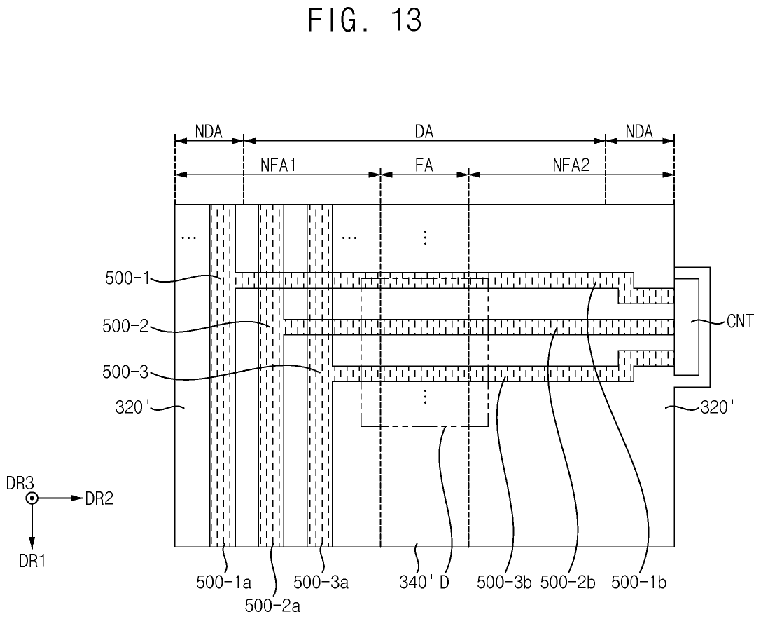

FIG. 12 is a cross-sectional view illustrating an example of a cross-section taken along line I-I′ of FIG. 1. FIG. 13 is a plan view illustrating an example of a digitizer 500 of FIG. 12. FIG. 14 is an enlarged view of area D of FIG. 13.

Hereinafter, a content which overlaps with a content described with reference to FIG. 4 will be omitted or simplified.

Referring to FIGS. 12 and 13, the display device DD may include a support member 300′ and a digitizer 500.

The support member 300′ may include a top layer 300′a, a bottom layer 300′b, and a middle layer 300′c. The top layer 300′a may be located on top of the digitizer 500 and closest to the display panel PNL. The bottom layer 300′b may be located under the digitizer 500 and further from the display panel PNL. The middle layer 300′c may be the remaining portion of the support member 300′ excluding the top layer 300′a and the bottom layer 300′b. For example, the support member 300′ may include the top layer 300′a disposed above a second wire 500b, the bottom layer 300′b disposed under a first wire 500a, and the middle layer 300′c excluding the top layer 300′a and the bottom layer 300′b. In other words, the middle layer 300′ may be disposed between the top layer 300′a and the bottom layer 300′b.

In an embodiment, the top layer 300′a, bottom layer 300′b, and middle layer 300′c may include a same material as each other. For example, the top layer 300′a, the bottom layer 300′b, and the middle layer 300′c may include glass fiber reinforced plastic (GFRP), carbon fiber reinforced plastic (CFRP), and the like. These may be used alone or in combination with each other.

In an embodiment, the top layer 300′a and the bottom layer 300′b may include a same material as each other, and the middle layer 300′c may include a different material from the upper and bottom layers 300′a and 300′b. For example, the top layer 300′a and the bottom layer 300′b may include polyimide (PI), and the middle layer 300′c may include glass fiber reinforced plastic. However, the present disclosure may not be limited to this.

The digitizer 500 may be implemented using an electromagnetic resonance (EMR) method, a pressure reduction method, a capacitance method, or a combination thereof. When an input tool or input device is applied to the display device DD, the input device and the digitizer 500 may communicate with each other to perform various input functions to the display device DD. For example, the input device may be an electromagnetic pen or a body part of a user. However, the input device of the present disclosure may not be limited to this.

The digitizer 500 may be located inside the support member 300′. The digitizer 500 may be within a thickness of the support member 300′, along the third direction DR3. The digitizer 500 may include a first wire 500a provided in plural including first wires 500a, a second wire 500b provided in plural including second wires 500b, and a connecting portion 500c.

The first wires 500a may be disposed on the upper portion of the bottom layer 300′b of the support member 300′. For example, the first wires 500a may contact the upper surface of the bottom layer 300′b of the support member 300′.

Each of the first wires 500a may extend in the first direction DR1, such as to have a major dimension along the first direction DR1. For example, the first wires 500a may be arranged across the display area DA and the non-display area NDA, along the first direction DR1. In addition, the first wires 500a may be arranged along the second direction DR2. In other words, the first wires 500a may extend in the first direction DR1 and be arranged along the second direction DR2.

The second wires 500b may be disposed under the top layer 300′a of the support member 300′. For example, the second wires 500b may contact the rear surface of the top layer 300′a of the support member 300′.

Each of the second wires 500b may extend in the second direction DR2, such as to have a major dimension along the second direction DR2. For example, the second wires 500b may be arranged across the foldable area FA, the first non-folding area NFA1 and the second non-folding area NFA2, along the second direction DR2. In addition, the second wires 500b may be arranged along the first direction DR1. In other words, each of the second wires 500b may extend in the second direction DR2 and may be arranged along the first direction DR1.

In an embodiment, the first wires 500a and the second wires 500b may be disposed in different layers or planes from each other. For example, the first wires 500a may be disposed under the second wires 500b.

However, the connecting wire 240 may be spaced apart from each of the first wires 500a and the second wires 500b. That is, the connecting wire 240 may not contact each of the first wires 500a and the second wires 500b.

The connecting portion 500c may connect the first wires 500a and the second wires 500b. Specifically, as the first wires 500a and the second wires 500b are disposed in a different layer, the connecting portion 500c may disposed between the first wires 500a and the second wires 500b which are in different layers from each other, to connect the first wires 500a and the second wires to each other.

One of a wire set is formed by a respective first wire among the first wires 500a, a respective second wire among the second wires 500b which overlaps the respective first wire, and a connecting portion connecting the respective first wire and the respective second wire to each other.

A plurality of wire sets may intersect with each other in a plane view, that is, along a planar direction. For example, a portion of a first wire set 500-1 and a portion of a second wire set 500-2 may intersect each other in a plane view. In other words, a portion of each of the first and second wire sets 500-1 and 500-2 may overlap each other. However, the wire sets may be spaced apart from each other in the cross-section. For example, the first wire set 500-1 and the second wire set 500-2 may be spaced apart from each other in cross-section, that is, along a thickness direction of the support member 300′. In an embodiment, an entirety of one wire set (e.g., first set layers along the thickness direction) may be spaced apart from an entirety of another wire set (e.g., second set layers along the thickness direction), without being limited thereto.

However, although three wire sets are shown in FIG. 13, the present disclosure may not be limited to this, and the digitizer 500 may include at least one wire set. In addition, although not shown in FIG. 13, the connecting wire 240 may be spaced apart from the wire set. For example, the connecting wire 240 may be disposed between the wire sets which are adjacent to each other.

Referring to FIGS. 13 and 14, the plurality of holes 360 may be arranged continuously and alternately throughout a stretchable portion 340′. For example, adjacent holes among the plurality of holes 360 may be arranged diagonally in the first direction DR1 and the second direction DR2.

As described above, the second wires 500b may extend from the flat portion 320′, in the second direction DR2. In the flat portion 320′, second wires 500b parallel to the second direction DR2 may be arranged in the first direction DR1. Accordingly, a first pattern P1 in which the second wires 500b are spaced apart at regular intervals in the first direction DR1, may be defined. In other words, the second wires 500b may include the first pattern P1 which overlaps the flat portion 320′.

However, since the plurality of holes 360 are defined in the stretchable portion 340′, the second wires 500b may not extend parallel to the second direction DR2 along the stretchable portion 340′. Accordingly, the second wires 500b may be arranged along a portion of the stretchable portion 340′ which is adjacent to (or defines) the plurality of holes 360. Specifically, the second wires 500b may include a second pattern P2 in a grid shape formed along the outer shape of the plurality of holes 360. In other words, the second wires 500b may include the second pattern P2 which overlaps the stretchable portion 340′. The planar shape of the holes 360 may be defined by sidewalls of the support member 300′ which defines the holes 360 therein. That is, the second wires 500b may extend along the sidewalls of the support member 300′ in a plan view, at the holes 360. Since material of the support member 300′ is absent at the holes 360 to define the holes 360, the material of the wires extends along material of the support member 300 which is around and defines the holes 360.

Referring to FIG. 13, a first sub-wire 500-1a of the first wire set 500-1, a first sub-wire 500-2a of the second wire set 500-2, and a first sub-wire 500-3a of a third wire set 500-3 may be spaced apart from each other along the second direction DR2, by a gap or space along the second direction DR2. A second sub-wire 500-1b of the first wire set 500-1, a second sub-wire 500-2b of the second wire set 500-2, and a second sub-wire 500-3b of a third wire set 500-3 may be spaced apart from each other along the first direction DR1 and along the second direction DR2, by a gap or space. A respective first sub-wire and a respective second sub-wire which is connected thereto, may provide a single body of a respective wire set.

Referring to the enlarged plan view of FIG. 14, the second sub-wire 500-1b, the second sub-wire 500-2b and the second sub-wire 500-3b continuously extend from a first area of the flat portion 320′, through the stretchable portion 340′, and into a second area of the flat portion 320′, in the second direction DR2 and to an end of the display device DD which is furthest along the second direction DR2. The gap in the second direction DR2 between the second sub-wires 500-1b, 500-2b, and 500-3b respectively adjacent to each other within the stretchable portion 340′ (e.g., at the foldable area FA of the display device DD), may be smaller than a gap in the second direction DR2 between each of the second sub-wires 500-1b, 500-2b, and 500-3b within the flat portion 320′. In other words, a gap between the second sub-wires 500-1b, 500-2b, and 500-3b respectively adjacent to each other along the second direction DR2 and forming the second pattern P2 at the foldable area FA of the display device DD may be smaller than a gap between the adjacent second sub-wires 500-1b, 500-2b, and 500-3b respectively adjacent to each other along the second direction DR2 and forming the first pattern P1 at the non-folding area of the display device DD.

As a respective sub-wire extends along a periphery of a hole 360 in the plan view, the respective sub-wire has an enclosed shape at the hole 360. More than one enclosed shape (e.g., a loop or the like) may be arranged along the foldable area FA of the display device DD. The enclosed shapes or loops may be connected to each other along the second direction DR2 by a connecting portion of the respective sub-wire. In an embodiment, the support member 300 defines holes 360 within the foldable portion, and each of the second wires 500b within the digitizer 500 has a first pattern P1 at the flat portion 320 of the support member 300 and a second pattern P2 which is at the foldable portion, connected to the first pattern P1 and surrounds the holes 360 of the support member 300.

A connector CNT may be located at a point where the first wires 500a and the second wires 500b meet each other or meet a same end surface of the display device DD. In an embodiment, the digitizer 500 may include the connector CNT connected to each of the first and second wires 500a and 500b. The connector CNT may be electrically connected to a printed circuit board (PCB) among the external devices, and may provide detection signals transmitted from the outside to the printed circuit board (PCB). Although not shown in FIGS. 13 and 14, the printed circuit board (PCB) may receive detection signals through the connector CNT and transmit a detection signals to an external device through the connector CNT.

FIG. 15 is a cross-sectional view illustrating an example of a cross-section taken along line I-I′ of FIG. 1.

Hereinafter, a content which overlaps with a content described with reference to FIGS. 4, 10, and 12 will be omitted or simplified.

Referring to FIG. 15, the display device DD may simultaneously include a connecting member 220′ and a digitizer 500. The connecting member 220′ may be an anisotropic conductive film, as described with reference to FIG. 10. The pad electrode 200′ (in FIG. 10) may have a concave-convex structure. The filling member FM (in FIG. 10) may be disposed on the pad electrode 200′.

The display device DD according to one or more of the embodiments may be applied as a display device DD included in an electronic device such as a computer, a notebook, a mobile phone, a smartphone, a smart pad, a PMP, a PDA, an MP3 player, or the like.

In an embodiment, a display device DD includes a display panel PNL includes a substrate 100 including a display area DA and a non-display area NDA which is adjacent to the display area DA, pixels PX which are on the substrate 100, in the display area DA, and a pad electrode 200 which is on the substrate 100, in the non-display area NDA, a support member 300 which overlaps the display area DA and the non-display area NDA and is under the substrate 100 of the display panel PNL, the support member 300 including a connecting wire 240 which is in the non-display area NDA, penetrates a thickness of the support member 300 and is electrically connected to the pad electrode 200, a connecting member 220 which contacts each of the pad electrode 200 of the display panel PNL and the connecting wire 240 of the support member 300 and connects the pad electrode 200 to the connecting wire 240.

In an embodiment, the support member 300 includes a connecting wire 240 which is in the non-display area NDA, penetrates a thickness of the support member 300 and is electrically connected to the pad electrode 200, and a digitizer 500 within the thickness of the support member 300. Here the digitizer 500 includes first wires 500a each extending in a first direction DR1 along the support member 300, and second wires 500b in a different plane than the first wires 500a, and each extending in a second direction DR2 intersecting the first direction DR1.

Although embodiments of the display device DD have been described with reference to the drawings, the illustrated embodiments are examples, and may be modified and changed by a person having ordinary knowledge in the relevant technical field without departing from the technical spirit described in the following claims.

What is claimed is:

1. A display device comprising:
a display panel comprising:
a substrate including a display area and a non-display area which is adjacent to the display area,
pixels which are on the substrate, in the display area, and
a pad electrode which is on the substrate, in the non-display area;
a support member which overlaps the display area and the non-display area and is under the substrate of the display panel;
the support member comprising a connecting wire which is in the non-display area, penetrates a thickness of the support member and is electrically connected to the pad electrode; and
a connecting member which contacts each of the pad electrode of the display panel and the connecting wire of the support member and connects the pad electrode to the connecting wire.

2. The display device of claim 1, wherein
the substrate defines a contact hole of the substrate, in the non-display area, and
the connecting member penetrates through a thickness of the pad electrode and further penetrates through a thickness of the substrate at the contact hole.

3. The display device of claim 2, wherein
the connecting wire of the support member is exposed to outside the substrate at the contact hole, and
the connecting member electrically connects the connecting wire of the support member and the pad electrode of the display panel, at the contact hole.

4. The display device of claim 1, further comprising a driving chip which provides signals and voltages to the pixels,
wherein
the support member further comprises an upper surface and a rear surface which is opposite to the upper surface along the thickness of the support member, and
the connecting wire which is in the non-display area includes:
a first portion contacting the connecting member at the upper surface of the support member;
a second portion contacting the driving chip at the rear surface of the support member; and
a third portion connecting the first portion and the second portion to each other.

5. The display device of claim 4, further comprising an electronic component which is adjacent to the driving chip and contacts the second portion of the connecting wire at the rear surface of the support member.

6. The display device of claim 4, wherein
the display area includes a foldable area with flexibility and a non-folding area which is adjacent to the foldable area, and
the support member further comprises:
a foldable portion overlapping the foldable area of the display area and having a lattice shape; and
a flat portion which overlaps the non-folding area of the display area and is adjacent to the foldable portion.

7. The display device of claim 6, wherein in a direction along the support member:
the first portion of the connecting wire extends from the third portion, in a direction away from the foldable portion, and
the second portion of the connecting wire extends from the third portion, in a direction towards the foldable portion.

8. The display device of claim 1, wherein the connecting member includes a conductive material.

9. The display device of claim 8, wherein the conductive material a solder paste or a silver paste.

10. The display device of claim 1, wherein the connecting member includes an anisotropic conductive film.

11. The display device of claim 1, wherein the support member includes glass fiber reinforced plastic.

12. The display device of claim 1, wherein along the substrate:
the display area and the non-display area are adjacent to each other along a first direction, and
the connecting member and the pad electrode which is connected to the connecting member, are provided in plural including connecting members and pad electrodes arranged along a second direction crossing the first direction.

13. A display device comprising:
a display panel comprising:
a substrate including a display area and a non-display area which is adjacent to the display area,
pixels which are on the substrate, in the display area, and
a pad electrode which is on the substrate, in the non-display area;
a support member which overlaps the display area and the non-display area and is under the substrate of the display panel;
the support member comprising:
a connecting wire which is in the non-display area, penetrates a thickness of the support member and is electrically connected to the pad electrode, and
a digitizer within the thickness of the support member, the digitizer comprising:
first wires each extending in a first direction along the support member, and
second wires in a different plane than the first wires, and each extending in a second direction intersecting the first direction, and
a connecting member which contacts each of the pad electrode of the display panel and the connecting wire of the support member and connects the pad electrode to the connecting wire.

14. The display device of claim 13, wherein within the support member:
the first wires are arranged along the second direction, and
the second wires are arranged along the first direction.

15. The display device of claim 13, wherein within the support member:
the first wires are under the second wires, and
the first wires and the second wires are electrically connected to each other.

16. The display device of claim 13, wherein the digitizer further includes a connector which electrically connect the first wires and the second wires to each other.

17. The display device of claim 13, wherein
the display area includes a foldable area with flexibility and a non-folding area which is adjacent to the foldable area, and
the support member further comprises:
a foldable portion overlapping the foldable area of the display area, and
a flat portion which overlaps the non-folding area of the display area and is adjacent to the foldable portion.

18. The display device of claim 17, wherein within the support member:
the support member defines holes within the foldable portion, and
each of the second wires within the digitizer has a first pattern at the flat portion of the support member and a second pattern which is at the foldable portion, connected to the first pattern and surrounds the holes of the support member.

19. The display device of claim 13, wherein the support member further comprises:
a top layer on the second wires,
a bottom layer under the first wires,
a middle layer excluding the top layer and the bottom layer,
the top layer and the bottom layer including a same material, and
the middle layer including a different material from each of the top layer and the bottom layer.

20. The display device of claim 13, wherein the connecting member includes an anisotropic conductive film.
